(19) United States
(12) Patent Application Publication
(10) Pub. No.: US 2018/0042105 A1
(43) Pub. Date: Feb. 8, 2018

(54) CAPACITIVE INTERPOSER FOR METAL SLOT ANTENNA AND METHODS

(71) Applicant: TAOGLAS GROUP HOLDINGS LIMITED, Enniscorthy (IE)

(72) Inventor: Christopher M. ANDERSON, Minneapolis, MN (US)

(73) Assignee: TAOGLAS GROUP HOLDINGS LIMITED, Enniscorthy (IE)

(21) Appl. No.: 15/657,536

(22) Filed: Jul. 24, 2017

Related U.S. Application Data
(60) Provisional application No. 62/370,362, filed on Aug. 3, 2016.

(51) Int. Cl. H05K 1/02; H01Q 1/22; H01Q 1/36; H01Q 1/48; H01Q 5/342; H01Q 13/10

(52) U.S. Cl. CPC H05K 1/0231; H01Q 5/342; H01Q 13/10; H01Q 1/36; H01Q 1/48; H01Q 1/2208

(57) ABSTRACT

A capacitive interposer with a flexible body is disclosed which engages a feed slot antenna exhibiting a range of bandwidths. As slot antennas are often manufactured within or otherwise incorporated into larger structures, the flexible body of the interposer allows the system to conform to a variety of surfaces.

### CROSS-REFERENCE

This application claims the benefit of U.S. Provisional Application No. 62/370,362, filed Aug. 3, 2016, entitled Capacitive Interposer for Metal Slot Antenna which application is incorporated herein by reference.

### BACKGROUND

Slot antennas offer the advantage of having virtually no height, therefore enabling the antenna to be flush with the surface in which it is manufactured. A typical slot antenna offers between 50 MHz and 500 MHz bandwidth depending on the center frequency, thus enabling coverage of one of one or more of wireless technology bands such as RKE, TPMs, Wi-Fi, Bluetooth, and DSRC, depending on the antenna's design. Often, the slot antenna is embedded directly or machined from the surface of a metallic, or otherwise conductive, structure such as a housing of a device or a part of a vehicle body. The slot antenna can be filled in and covered with any low permittivity dielectric in order to be visually hidden.

Feeds for slot antennas often consist of coaxial cables which are attached by soldering. The precision with which the feed is placed in relation to the radiating slot impacts performance. This often requires a complicated jig or fixture to ensure proper placement and/or per-unit tuning or adjustment at assembly time. Also, there are numerous applications of slot antennas for which cable soldering to the surface thereof is impossible or impractical.

What is needed is a capacitive interposer with a flexible body which provides a simple, reliable and repeatable way to attach a feed to a slot antenna.

### SUMMARY

A capacitive interposer with a flexible body is disclosed to feed slot antennas exhibiting a range of bandwidths. As slot antennas are often manufactured within or otherwise incorporated into larger structures, the flexible body of the interposer allows it to conform to a variety of shapes. The capacitive interposer can be used for any frequency.

The disclosed interposer facilitates robust, reliable and repeatable coaxial cable feeding of a metal slot antenna to a desired feed location, particularly where cable soldering to the antenna surface is impossible, impractical, or otherwise undesirable.

Disclosed are flexible capacitive interposers. Suitable flexible capacitive interposers comprise: a planar, flexible interposer body having a top surface and a bottom surface, and a plurality of sides; an adhesive surface positioned on at least one of the top surface and the bottom surface; a first coaxial cable attachment point and a second coaxial cable attachment point positioned on the planar, flexible interposer body, wherein the planar, flexible interposer body is affixable at a first side to a first end of a coaxial cable. The planar, flexible interposer body can further comprise a polygon shape adjacent a second shape, such as a rectangular shape. In some configurations, the planar, flexible interposer body has a circular shape and a second rectangular shape. The first coaxial cable attachment point is positionable on the polygon shape and the second coaxial cable attachment point is positioned on the rectangular shape. The polygon shape has two sets of parallel sides and one set of sides which are non-parallel.

Another aspect of the disclosure is directed to flexible capacitive interposer systems. Suitable systems comprise: a coaxial cable having a first end and a second end; and a flexible capacitive interposer having a planar, flexible interposer body having a top surface and a bottom surface, and a plurality of sides; an adhesive surface positioned on at least one of the top surface and the bottom surface; a first coaxial cable attachment point and a second coaxial cable attachment point positioned on the planar, flexible interposer body, wherein the planar, flexible interposer body is affixable at a first side to a first end of a coaxial cable; and a connector affixed to the second end of the coaxial cable. The planar, flexible interposer body comprises a polygon shape adjacent another shape, such as a rectangular shape. The planar, flexible interposer body can have a circular shape and a second rectangular shape. The first coaxial cable attachment point is positioned on the polygon shape and the second coaxial cable attachment point is positioned on the rectangular shape. Additionally, the polygon shape can further have two sets of parallel sides and one set of sides which are non-parallel.

Still another aspect of the disclosure is directed to methods of using a flexible capacitive interposer system. Suitable methods comprise: providing a flexible capacitive interposer having a planar, flexible interposer body having a top surface and a bottom surface, and a plurality of sides; an adhesive surface positioned on at least one of the top surface and the bottom surface; a first coaxial cable attachment point and a second coaxial cable attachment point positioned on the planar, flexible interposer body, wherein the planar, flexible interposer body is affixable at a first side to a first end of a coaxial cable; and connecting a coaxial cable to the flexible capacitive interposer at a first coaxial cable attachment point and a second coaxial cable attachment point; and applying the adhesive surface of the flexible capacitive interposer to a target location on a surface. The flex can have an alignment where holes in it line up with permanent or temporary alignment pins on a mounting surface to ensure precise location of the flex circuit assembly. Additionally, the flexible capacitive interposer can be conformed to a non-planar target location. Moreover, removing the flexible capacitive interposer from the target surface and positioning the flexible capacitive interposer at a new target location.

Disclosed are flexible capacitive interposers. Suitable flexible capacitive interposer means comprise: a planar, flexible interposer body means having a top surface and a bottom surface, and a plurality of sides; an adhesive surface positioned on at least one of the top surface and the bottom surface; a first coaxial cable attachment point and a second coaxial cable attachment point positioned on the planar, flexible interposer body, wherein the planar, flexible interposer body means is affixable at a first side to a first end of a coaxial cable. The planar, flexible interposer body means can further comprise a polygon shape adjacent a second shape, such as a rectangular shape. In some configurations, the planar, flexible interposer body means has a circular shape and a second rectangular shape. The first coaxial cable attachment point is positionable on the polygon shape and the second coaxial cable attachment point is positioned on the rectangular shape. The polygon shape has two sets of parallel sides and one set of sides which are non-parallel.

Another aspect of the disclosure is directed to flexible capacitive interposer systems. Suitable systems comprise: a coaxial cable having a first end and a second end; and a flexible capacitive interposer having a planar, flexible interposer body means having a top surface and a bottom surface, and a plurality of sides; an adhesive surface positioned on at least one of the top surface and the bottom surface; a first coaxial cable attachment point and a second coaxial cable attachment point positioned on the planar, flexible interposer body, wherein the planar, flexible interposer body means is affixable at a first side to a first end of a coaxial cable; and a connector affixed to the second end of the coaxial cable. The planar, flexible interposer body means comprises a polygon shape adjacent another shape, such as a rectangular shape. The planar, flexible interposer body means can have a circular shape and a second rectangular shape. The first coaxial cable attachment point is positioned on the polygon shape and the second coaxial cable attachment point is positioned on the rectangular shape. Additionally, the polygon shape can further have two sets of parallel sides and one set of sides which are non-parallel.

Still another aspect of the disclosure is directed to methods of using a flexible capacitive interposer system. Suitable methods comprise: providing a flexible capacitive interposer having a planar, flexible interposer body means having a top surface and a bottom surface, and a plurality of sides; an adhesive surface positioned on at least one of the top surface and the bottom surface; a first coaxial cable attachment point and a second coaxial cable attachment point positioned on the planar, flexible interposer body, wherein the planar, flexible interposer body means is affixable at a first side to a first end of a coaxial cable; and connecting a coaxial cable to the flexible capacitive interposer at a first coaxial cable attachment point and a second coaxial cable attachment point; and applying the adhesive surface of the flexible capacitive interposer to a target location on a surface. The flex can have an alignment where holes in it line up with permanent or temporary alignment pins on a mounting surface to ensure precise location of the flex circuit assembly. Additionally, the flexible capacitive interposer can be conformed to a non-planar target location. Moreover, removing the flexible capacitive interposer from the target surface and positioning the flexible capacitive interposer at a new target location.

### INCORPORATION BY REFERENCE

All publications, patents, and patent applications mentioned in this specification are herein incorporated by reference to the same extent as if each individual publication, patent, or patent application was specifically and individually indicated to be incorporated by reference. See, for example:

U.S. Pat. No. 5,155,493 A issued on Oct. 13, 1992 to Thursby, et al., for Tape type microstrip antenna;

U.S. Pat. No. 6,054,961 A issued on Apr. 25, 2000 to Gong, et al., for Dual band, glass mount antenna and flexible housing therefor;

U.S. Pat. No. 6,828,941 B2 issued on Dec. 7, 2004 to King, et al., for Wireless communication device and method;

U.S. Pat. No. 7,300,863 B2 issued on Nov. 27, 2007 to Pennaz, et al., for Circuit chip connector and method of connecting a circuit chip;

U.S. Pat. No. 7,504,952 B2 issued on Mar. 17, 2009 to Kaplan, et al., for Wide band RFID system with tag on flexible label;

U.S. Pat. No. 7,701,352 B2 issued on Apr. 20, 2010 to Forster for RFID label with release liner window and method of making;

U.S. Pat. No. 8,072,334 B2 issued on Dec. 6, 2011 to Forster, et al., for RFID tag with enhanced readability;

U.S. Pat. No. 8,441,113 B2 issued on May 14, 2013 to Lee for Elimination of RDL using tape base flip chip on flex for die stacking;

U.S. Pat. No. 8,746,577 B2 issued on Jun. 10, 2014 to Bernhard, et al., for Placement insensitive antenna for RFID, sensing and/or communication systems;

CN 104485522 A issued on Apr. 11, 2015 for Dual-polarized slot coupling antenna;

WO 2008055578 A1 issued on May 15, 2008 to Bohn for Self-adhesive RFID-label and method for the production thereof;

Laisne, et al., for Robust slot-fed dielectric resonator antenna using an intermediate substrate, Electronics Letters 37. 25: 1497-8 published on Dec. 6, 2001; and

Ruyle, Small, Dual Band, Placement Insensitive Antennas, Dissertation, University of Illinois at Urbana-Champaign, 2011.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings of which:

FIG. 1A is a table of exemplar specification ranges for mechanical and environmental features for a capacitive interposer according to the disclosure;

FIG. 1B is a top view of one embodiment of a capacitive interposer according to the disclosure; and

FIG. 2 is a schematic drawing of the desired positioning of a capacitive interposer with respect to a typical slot antenna according to the disclosure.

### DETAILED DESCRIPTION

A flexible capacitive interposer that provides an electrical interface is disclosed. The flexible interposer can be used to feed a metal slot antenna to a desired feed location. The flexible interposer enables coaxial cable feeding of a metal slot antenna. The flexible interposer can be used for applications where cable soldering of the coaxial cable is impractical.

Attachment of the flexible capacitive interpose to external electronics is achieved via a coaxial cable with standard IPEX connector. The interposer body may be formed from flexible polymer material with adhesive backing to facilitate attachment to the antenna structure. The flexible capacitive interpose can have holes in it to line up with permanent or temporary alignment pins on a mounting surface to ensure precise location of the flex circuit assembly.

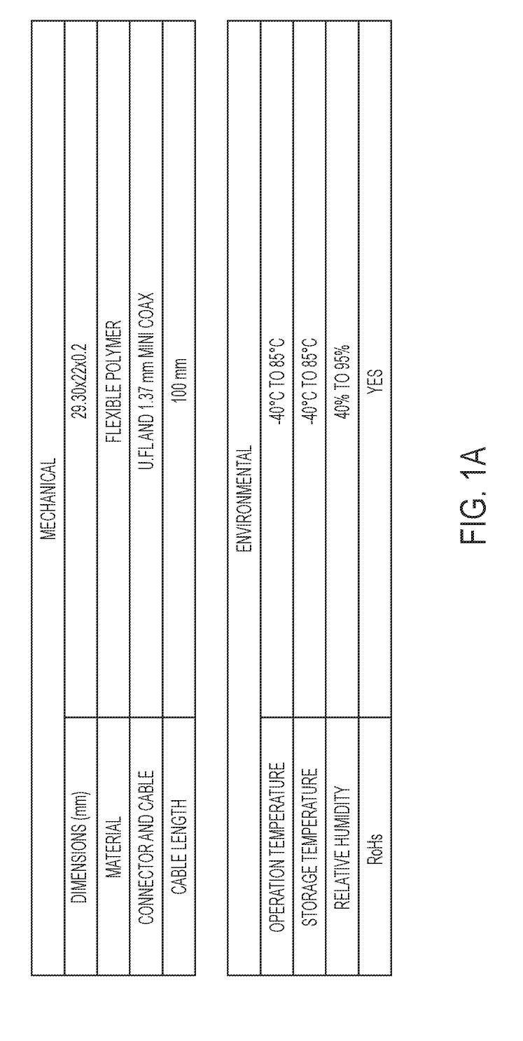

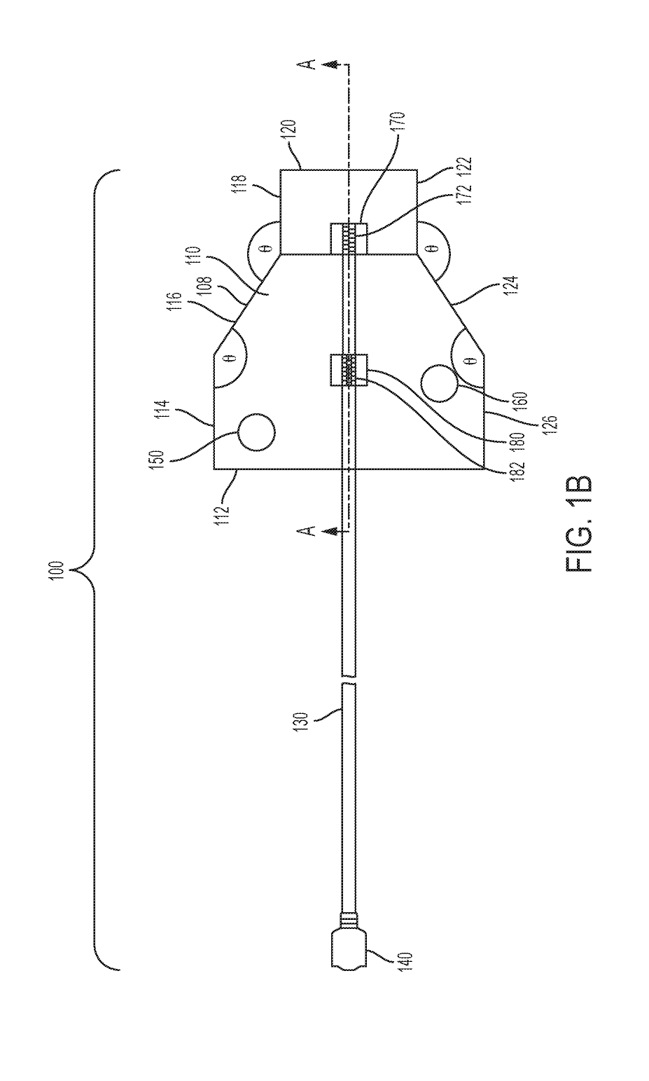

FIG. 1A lists mechanical and environmental specifications for an exemplar interposer according to the disclosure. Details include exemplar mechanical and environmental parameters. Exemplar mechanical parameters include dimension of from 29.30 mm×22 mm×0.2 mm, material of flexible polymer, connector and cable U.FL and 1.37 mm Mini Coax; and a cable length up to, for example, 100 mm. Other dimensions can be used without departing from the scope of the disclosure. Exemplar environmental specifications include an operation temperature of between about −40° C. and 85° C.; storage temperature range of between about −40° C. and 85° C.; relative humidity of about 40% to about 95%; and Restriction of Hazard (RoH) YES.

FIG. 1B illustrates a top view of an embodiment of a flexible capacitive interposer 100 according to the disclosure. Flexible capacitive interposer 100 comprises an interposer body 108, a coaxial cable 130 and an connector 140, such as an I-PEX micro RF Coax available from Dai-ichi Seiko Co., Ltd (Japan). The interposer body 108 is planar consisting of thin, flat, flexible polymer, which allows it to conform to various antenna structures. Interposer body 108 has a top surface 110 and a bottom surface (not shown in FIG. 1B) opposite the top surface 110. The bottom surface has an adhesive coating, allowing the interposer body 108 to be attached to an antenna structure. The adhesive coating may be any adhesive which is suitable for bonding to the structure of a typical slot antenna. Suitable adhesive includes, for example, VHB™ adhesive tape from 3M™. Installation may be achieved via simple “peel and stick” process.

In different embodiments of flexible capacitive interposer 100, the shape of interposer body 108 may be defined to facilitate alignment or attachment to different slot antenna structures. In the exemplar embodiment of flexible capacitive interposer 100 depicted in FIG. 1B, interposer body 108 has a first side 112, a second side 114, a third side 116, a fourth side 118, a fifth side 120, a sixth side 122, a seventh side 124, and an eighth side 126, numbered clockwise when viewed from the top. First side 112 is the longest side of the resulting polygonal shape of the interposer body 108. The second side 114 and the eighth side 126 are positioned on opposing sides of the interposer body 108 and have equal side lengths. The second side 114 and the eighth side 126 extend perpendicular from either end of first side 112. From the other ends of second side 114 and eighth side 126, third side 116 and seventh side 124 extend, respectively, at equal angles θ, as illustrated, such that the plan view of the interposer body 108 tapers compared to the length of first side 112.

From the other ends of third side 116 and seventh side 124, fourth side 118 and sixth side 122, which are equal length, extend respectively at equal angles θ, as illustrated, such that they are parallel to second side 114 and eight side 126. Fifth side 120 runs from the other end of fourth side 118 to the other end of sixth side 122 and is parallel first side 112 and closes the polygon which constitutes the shape of interposer body 108. The resulting polygon exhibits symmetry about the perpendicular bisector which runs from the midpoint of first side 112 to the midpoint of fifth side 120, denoted by line A-A in the illustration. Two coaxial cable attachment points are provided: a first coaxial cable attachment point 170 and a second coaxial cable attachment point 180. First coaxial cable attachment point 170 is rectangular in shape and is located in the narrow section of the interposer body 108 along the perpendicular bisector of the interposer body 108, denoted by line A-A in the illustration between fourth side 118 and sixth side 122. Both first coaxial cable attachment point 170 and second coaxial cable attachment point 180 are of copper and are typically fabricated via metal-plating process, although other conductive materials and construction methods may be employed. The inner conductor 172 of coaxial cable 130 is attached to the interposer body at the first coaxial cable attachment point 170, typically via surface mount solder joint, although other methods such as conductive epoxy, with suitable electrical and physical properties, reliability, and robustness, may be employed. Coaxial cable 130 itself may also be adhesively bonded to interposer body 108 to maintain proper routing and/or to provide strain relief for the conductive joints at first coaxial cable attachment point 170 and second coaxial cable attachment point 180.

Second coaxial cable attachment point 180 is rectangular in shape and is located in the wide section of the interposer body 108 between second side 114 and eighth side 126. The outer conductor 182 of the coaxial cable 130 is attached to the interposer body 108 at the second coaxial cable attachment point 180, typically via solder joint, although other methods such as conductive epoxy, with suitable electrical and physical properties, reliability, and robustness, may be employed.

To ensure best antenna performance, interposer body 108 includes features to facilitate desired alignment with respect to the slot antenna structure upon which it is attached. Such features may consist of markings, apertures, or other defining geometry such as peripheral notches. In the embodiment depicted in FIG. 1B, interposer body 108 has two alignment features: a first alignment aperture 150 and a second alignment aperture 160. First alignment aperture 150 and second alignment aperture 160 are elliptical, of equal size, and are located in the wide section of interposer body 108. The longitudinal axes of both first alignment aperture 150 and second alignment aperture 160 are parallel to first side 112 of interposer body 108, with first alignment aperture 150 positioned nearer first side 112 than second alignment aperture 160 within interposer body 108.

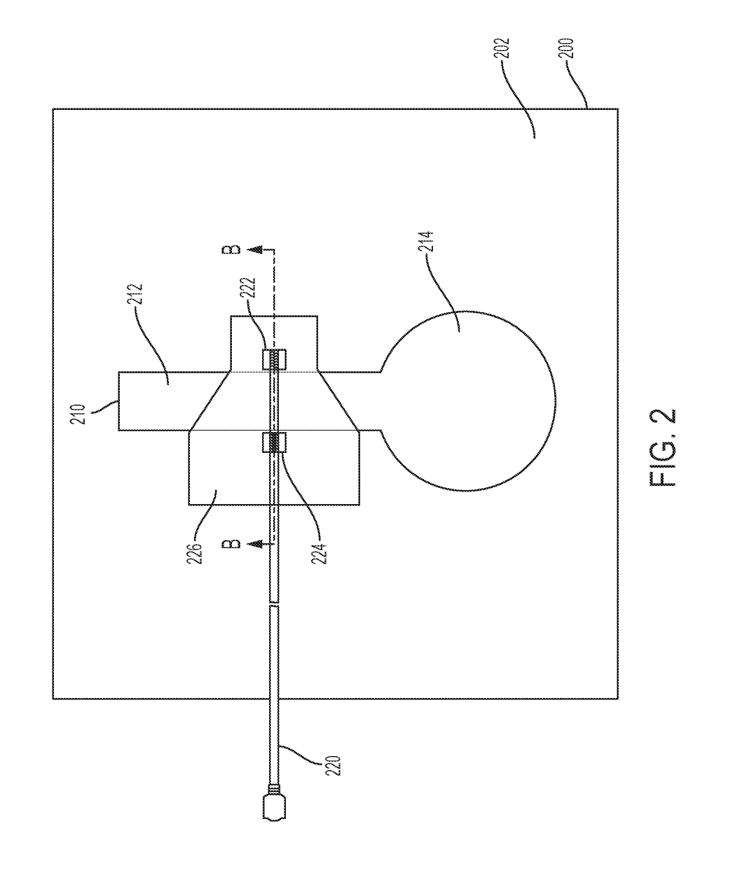

FIG. 2 illustrates the desired positioning of a capacitive interposer with respect to a typical slot antenna according to the disclosure. FIG. 2 illustrates a metallic body 200 with top surface 202. The metallic body 200 may be part of a larger structure or module or assembly, such as a vehicle body or frame, or it may be a structure in its entirety. An antenna aperture 210 is machined or otherwise cut or fabricated into top surface of the metallic body 200. The antenna aperture 210 consists of a rectangular section 212 and a circular section 214, that intersect or overlap so that resulting shape of antenna aperture 210 resembles a keyhole or lollipop.

Residing on metallic body 200 is a capacitive interposer 220 similar to the capacitive interposer described in FIG. 1B. As noted in the FIG. 2, the capacitive interposer 220 has a first coaxial cable attachment point 222 and a second coaxial cable attachment point 224, positioned on the interposer body 226 as described in FIG. 1B. Interposer body 226 is positioned over the rectangular section 212 of antenna aperture 210 such that a line running from the middle of first coaxial cable attachment point 222 through the middle of second coaxial cable attachment point 224, denoted by line B-B in FIG. 2, is perpendicular to the long sides of the rectangular section 212 of antenna aperture 210 and such that first coaxial cable attachment point 222 and second coaxial cable attachment point 224 rest on opposite sides of rectangular section 212, thus spanning the antenna aperture 210. Interposer body 226 is fixed to metallic body 200 via adhesive bonding.

While preferred embodiments of the present invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention. It is intended that the following claims define the scope of the invention and that methods and structures within the scope of these claims and their equivalents be covered thereby.

1. A flexible capacitive interposer comprising:
a planar, flexible interposer body having a top surface and a bottom surface, and a plurality of sides;
an adhesive surface positioned on at least one of the top surface and the bottom surface;
a first coaxial cable attachment point and a second coaxial cable attachment point positioned on the planar, flexible interposer body,
wherein the planar, flexible interposer body is affixable at a first side to a first end of a coaxial cable.

2. The flexible capacitive interposer of claim 1 wherein the planar, flexible interposer body comprises a polygon shape adjacent a second shape.

3. The flexible capacitive interposer of claim 1 further comprising a slot antenna having a circular shape and a rectangular shape.

4. The flexible capacitive interposer of claim 2 wherein the first coaxial cable attachment point is positioned on the polygon shape and the second coaxial cable attachment point is positioned on the second shape.

5. The flexible capacitive interposer of claim 2 wherein the polygon shape has two sets of parallel sides and one set of sides which are non-parallel.

6. A flexible capacitive interposer system comprising:
a coaxial cable having a first end and a second end; and
a flexible capacitive interposer having
a planar, flexible interposer body having a top surface and a bottom surface, and a plurality of sides;
an adhesive surface positioned on at least one of the top surface and the bottom surface;
a first coaxial cable attachment point and a second coaxial cable attachment point positioned on the planar, flexible interposer body,
wherein the planar, flexible interposer body is affixable at a first side to a first end of a coaxial cable; and
a connector affixed to the second end of the coaxial cable.

7. The flexible capacitive interposer system of claim 6 wherein the planar, flexible interposer body comprises a polygon shape adjacent a rectangular shape.

8. The flexible capacitive interposer system of claim 7 further comprising a slot antenna having a circular shape and a rectangular shape.

9. The flexible capacitive interposer system of claim 7 wherein the first coaxial cable attachment point is positioned on the polygon shape and the second coaxial cable attachment point is positioned on the rectangular shape.

10. The flexible capacitive interposer system of claim 7 wherein the polygon shape has two sets of parallel sides and one set of sides which are non-parallel.

11. A method of using a flexible capacitive interposer system comprising:
providing a flexible capacitive interposer having
a planar, flexible interposer body having a top surface and a bottom surface, and a plurality of sides;
an adhesive surface positioned on at least one of the top surface and the bottom surface;
a first coaxial cable attachment point and a second coaxial cable attachment point positioned on the planar, flexible interposer body,
wherein the planar, flexible interposer body is affixable at a first side to a first end of a coaxial cable; and
connecting a coaxial cable to the flexible capacitive interposer at a first coaxial cable attachment point and a second coaxial cable attachment point; and
applying the adhesive surface of the flexible capacitive interposer to a target location on a surface.

12. The method of claim 11 further comprising the step of:
conforming the flexible capacitive interposer to a non-planar target location.

13. The method of claim 11 further comprising the step of:
removing the flexible capacitive interposer from the target surface and positioning the flexible capacitive interposer at a new target location.
